(19) United States
(12) Patent Application Publication
(10) Pub. No.: US 2016/0013165 A1
(43) Pub. Date: Jan. 14, 2016

(54) LIGHT EMITTING DEVICE

(71) Applicant: TOYODA GOSEI CO., LTD., Kiyosu-shi (JP)

(72) Inventors: Yosuke TSUCHIYA, Kiyosu-shi (JP); Shota SHIMONISHI, Kiyosu-shi (JP); Shigeo TAKEDA, Kiyosu-shi (JP); Tomohiro MIWA, Kiyosu-shi (JP)

(21) Appl. No.: 14/724,674

(22) Filed: May 28, 2015

(30) Foreign Application Priority Data
Jul. 14, 2014 (JP) 2014-144349

(51) Int. Cl. H01L 25/075

(52) U.S. Cl. CPC H01L 25/0753

(57) ABSTRACT

A light emitting device includes a plurality of light emitting elements. A difference between a maximum value and a minimum value of an inherent threshold voltage of the plurality of light emitting elements is not less than 0.5 V. A difference between a maximum value and a minimum value of a threshold voltage of the plurality of light emitting elements is not more than 0.1 V when temperature of the light emitting device is stabilized in operation.

The present application is based on Japanese patent application No. 2014-144349 filed on Jul. 14, 2014, the entire contents of which are incorporated herein by reference.

### BACKGROUND OF THE INVENTION

1. Field of the Invention

This invention relates to a light emitting device.

2. Description of the Related Art

An LED lighting device is known in which multiple light emitting elements (i.e., LED chips) are densely disposed (see e.g. JP-A-2003-124528).

### SUMMARY OF THE INVENTION

If multiple light emitting elements are densely disposed as disclosed in JP-A-2003-124528, among the light emitting elements, a light emitting element disposed near the center is likely to increase in temperature during operation, thereby the light emitting element may decrease in threshold voltage. Thus, even if the multiple light emitting elements are initially provided with a same threshold voltage, the threshold voltage may be dispersed among them during operation so that the light emitting device becomes uneven in brightness.

It is an object of the invention to provide a light emitting device that emits light with a high evenness in brightness even if multiple light emitting elements are densely disposed therein.

(1) According to one embodiment of the invention, a light emitting device comprises a plurality of light emitting elements,

wherein a difference between a maximum value and a minimum value of an inherent threshold voltage of the plurality of light emitting elements is not less than 0.5 V, and

wherein a difference between a maximum value and a minimum value of a threshold voltage of the plurality of light emitting elements is not more than 0.1 V when temperature of the light emitting device is stabilized in operation.

In the above embodiment (1) of the invention, the following modifications and changes can be made.

(i) Among the plurality of light emitting elements, a light emitting element disposed at a nearest position to a center of the device has a highest inherent threshold voltage and a light emitting element disposed at a farthest position from the center has a lowest inherent threshold voltage.

(ii) In a plan view, the plurality of light emitting elements have a same shape and size and are aligned in direction, wherein, in a plan view, an element interval of the plurality of light emitting elements in a longitudinal direction is 0.1 to 1.0 times of a width of the light emitting elements in the longitudinal direction, and wherein, in a plan view, an element interval of the plurality of light emitting elements in a transverse direction is 0.1 to 1.0 times of a width of the light emitting elements in the transverse direction.

(iii) The plurality of light emitting elements are series-connected to each other.

(iv) The inherent threshold voltage of the plurality of light emitting elements is not less than 2.5 V and not more than 3.5 V.

Effects of the Invention

According to one embodiment of the invention, a light emitting device can be provided that emits light with a high evenness in brightness even if multiple light emitting elements are densely disposed therein.

### BRIEF DESCRIPTION OF THE DRAWINGS

The preferred embodiments according to the invention will be explained below referring to the drawings, wherein:

FIG. 1 is a top view showing a light emitting device according to a first embodiment of the invention; and

FIG. 2 is a vertical cross-sectional view taken along a chain line A-A in FIG. 1.

### DETAILED DESCRIPTION OF THE PREFERRED EMBODIMENTS

### First Embodiment

(Configuration of light emitting device)

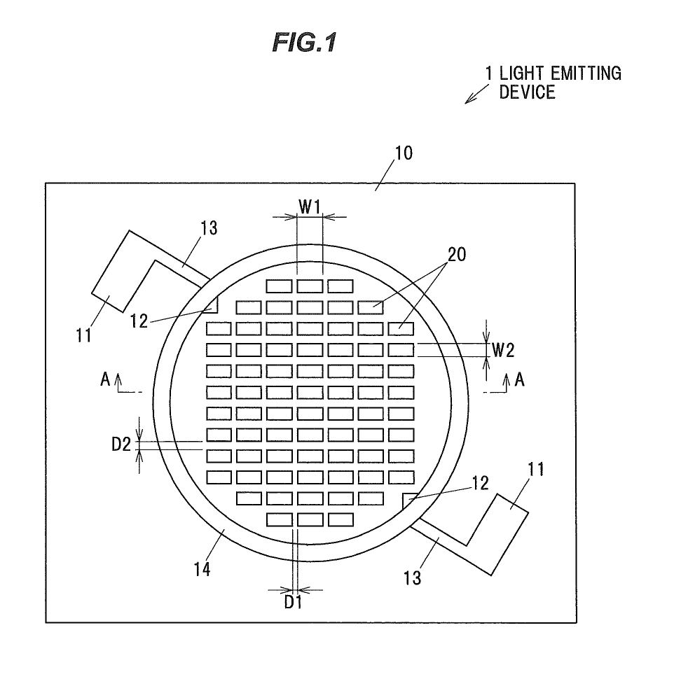

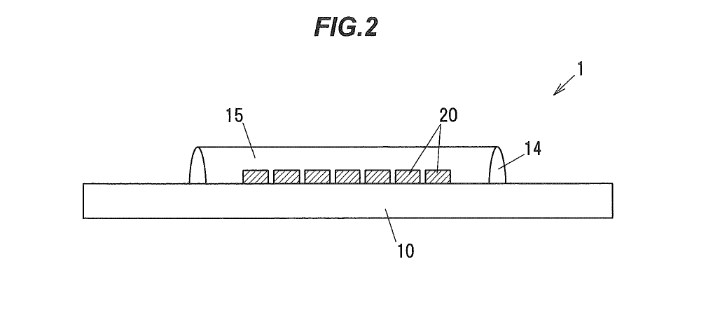

FIG. 1 is a top view schematically showing a light emitting device according to a first embodiment of the invention. FIG. 2 is a vertical cross-sectional view taken along the chain line A-A in the light emitting device of FIG. 1.

The light emitting device 1 includes a substrate 10, a plurality of light emitting elements 20 disposed on the substrate 10, a dam 14 surrounding the light emitting elements 120 and a sealing resin 15 filled inside the dam 14 so as to seal the light emitting elements 20. In FIG. 1, illustration of the sealing resin 15 is omitted.

The substrate 10 is a substrate that has wiring, for example, the substrate 10 is a wiring substrate or a lead frame insertion substrate that has a wiring pattern on the surface thereof.

The light emitting element 20 is an LED (Light Emitting Diode) or a laser diode, and includes a chip substrate and a crystal layer including a light emitting layer sandwiched between an n-type clad layer and a p-type clad layer.

The light emitting elements 20 are connected to each other via a bonding wire, a wiring of the substrate 10 or the like. In an example shown in FIG. 1, the light emitting device 1 includes a wire bonding terminal 12 to which the light emitting element 20 located at the end of the connection is connected via a bonding wire. The wire bonding terminal 12 is connected to an external connection terminal 11 via a wiring electrode 13, and power is supplied from an outside power source via the external connection terminal 11.

The light emitting elements 20 are densely disposed in an element mounting region that is a region located inside the dam 14. For example, in case that in a plan view, the plurality of the light emitting elements 20 have a homogeneous shape and size and the direction thereof is aligned, and in a plan view, the element interval D1 of the plurality of the light emitting elements 20 in the longitudinal direction is 0.1 to 1.0 times of the width W1 of the light emitting elements in the longitudinal direction, and in a plan view, the element interval D2 of the plurality of the light emitting elements 20 in the transverse direction is 0.1 to 1.0 times of the width W2 of the light emitting elements 20 in the transverse direction. Further, even if the widths W1, W2 are not constant, the above-mentioned condition is equally adopted.

The light emitting elements 20 are densely disposed, thus at the time of operation of the light emitting device 1, the light emitting elements 20 are easily increased in temperature by heat generated from the light emitting elements 20 adjacent to each other. In addition, among the light emitting elements 20, the light emitting elements which a large number of the light emitting elements are adjacent to, and are located near the center of the element mounting region are more increased in temperature than the light emitting elements which a small number of the light emitting elements are adjacent to, and are located at the outer side of the element mounting region. The light emitting element has a property that the more the temperature thereof is increased, the more the threshold voltage thereof is reduced, thus the more the light emitting element is located near the center of the element mounting region, the more the threshold voltage thereof is reduced at the time of operation of the light emitting device 1.

In consideration with the above-mentioned increasing part of the temperature at the time of operation of the light emitting device 1, the light emitting elements 20 are designed such that the threshold voltage thereof becomes approximately homogeneous in a state that the temperature at the time of operation of the light emitting device 1 is stabilized.

For example, a difference between the maximum value and the minimum value of an inherent threshold voltage (a threshold voltage in case that the light emitting element is made to emit a light as a single body) of the light emitting elements 20 is not less than 0.5 V, and a difference between the maximum value and the minimum value of a threshold voltage of the light emitting elements 20 becomes not more than 0.1 V in a state that the temperature thereof at the time of operation of the light emitting device 1 is stabilized. Further, the inherent threshold voltage of the plurality of the light emitting elements 20 falls within the range of, for example, 2.5 to 3.5 V.

In addition, as mentioned above, among the light emitting elements 20, the more the light emitting element is located near the center of the element mounting region, the more the threshold voltage thereof is reduced at the time of operation of the light emitting device 1. Thus, it is preferable that the light emitting elements 20 are configured such that the light emitting element disposed at the nearest position to the center has the highest inherent threshold voltage, and the light emitting element disposed at the farthest position from the center has the lowest inherent threshold voltage.

In addition, it is preferable that all of the light emitting elements 20 are connected to each other in series. The more the light emitting element 20 is located near the center of the element mounting region, the more the threshold voltage thereof is heightened, thus in a state that the temperature thereof is not stabilized, just after starting the operation of the light emitting device 1, the more the light emitting element 20 is located near the center of the element mounting region, the more the brightness is reduced. Here, in case that the light emitting elements 20 are connected to each other in parallel every several groups, it is difficult for electric current to flow through the group that includes the light emitting elements 20 of which threshold voltage is high, the element 20 being located near the center of the element mounting region, thus a difference in brightness between the light emitting elements 20 located at the outer side of the element mounting region and the light emitting elements 20 located near the center of the element mounting region is increased.

The dam 14 is comprised of, for example, a resin such as a silicone based resin or an epoxy based resin that contains a white dye such as titanium oxide.

The sealing resin 15 is comprised of, for example, a transparent resin such as a silicone based resin or an epoxy based resin. In addition, the sealing resin 15 may include fillers comprised of SiO₂ or the like for the purpose of scattering a light, and phosphor particles. For example, in case that the light emitting color of the light emitting elements 20 is blue and the fluorescent color of the phosphor particles included in the sealing resin 15 is yellow, the light emitting color of the light emitting device 1 becomes white.

It should be noted that in the light emitting device 1, disposition, shape, size, number and the like of the light emitting elements 20 are not limited to those shown in FIGS. 1 and 2.

(Advantageous Effect of Embodiment)

According to the above-mentioned embodiment, a plurality of the light emitting elements 20 are designed such that the threshold voltage thereof becomes approximately homogeneous at the time of operation of the light emitting device 1, thereby the light emitting device 1 can be enhanced in homogeneity of the light emission brightness thereof.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

Also, it should be noted that the above-mentioned embodiment(s) does not limit the construe of the appended claims. In particular, it should be noted that all of the combinations of features as described in the embodiment(s) are not always needed to solve the problem of the invention.

What is claimed is:

1. A light emitting device, comprising a plurality of light emitting elements,
wherein a difference between a maximum value and a minimum value of an inherent threshold voltage of the plurality of light emitting elements is not less than 0.5 V, and
wherein a difference between a maximum value and a minimum value of a threshold voltage of the plurality of light emitting elements is not more than 0.1 V when temperature of the light emitting device is stabilized in operation.

2. The light emitting device according to claim 1, wherein among the plurality of light emitting elements, a light emitting element disposed at a nearest position to a center of the device has a highest inherent threshold voltage and a light emitting element disposed at a farthest position from the center has a lowest inherent threshold voltage.

3. The light emitting device according to claim 1, wherein, in a plan view, the plurality of light emitting elements have a same shape and size and are aligned in direction, wherein, in a plan view, an element interval of the plurality of light emitting elements in a longitudinal direction is 0.1 to 1.0 times of a width of the light emitting elements in the longitudinal direction, and
wherein, in a plan view, an element interval of the plurality of light emitting elements in a transverse direction is 0.1 to 1.0 times of a width of the light emitting elements in the transverse direction.

4. The light emitting device according to claim 1, wherein the plurality of light emitting elements are series-connected to each other.

5. The light emitting device according to claim 1, wherein the inherent threshold voltage of the plurality of light emitting elements is not less than 2.5 V and not more than 3.5 V.
